(19) United States
(12) Patent Application Publication
(10) Pub. No.: US 2012/0174970 A1
(43) Pub. Date: Jul. 12, 2012

(54) TERMINAL BOX FOR USE WITH SOLAR CELL MODULE

(75) Inventors: Hiroyuki Yoshikawa, Yokkaichi-shi (JP); Masayoshi Hashimoto, Yokkaichi-shi (JP); Makoto Higashikozono, Yokkaichi-shi (JP); Tomoya Kawaguchi, Yokkaichi-shi (JP)

(73) Assignee: SUMITOMO WIRING SYSTEMS, LTD., Yokkaichi-shi (JP)

(21) Appl. No.: 13/496,707

(22) PCT Filed: Jul. 29, 2010
(86) PCT No.: PCT/JP2010/062768

§ 371 Date: Mar. 16, 2012

(30) Foreign Application Priority Data
Nov. 5, 2009 (JP) 2009-253746

(51) Int. Cl. H01L 31/0224

(52) U.S. Cl. 136/252

(57) ABSTRACT

Disclosed is a terminal box for a solar cell module, which has improved heat transfer properties. Specifically, disclosed is a terminal box for a solar cell module with a plurality of terminal boards (60), a case (10) which contains the terminal boards (60) and has an outer periphery (12) that surrounds the peripheries of the terminal boards (60); a bypass diode (80) which is connected to two corresponding terminal boards (60) and serve as a bypass for a reverse load; a radiator plate (60) which supports a rectifying device body (81) that is a heat generating portion of the bypass diode. The radiator plate (60) is being formed integrally with or separately from the terminal board (60); and a bottom (11) arranged between the radiator plate (60) and the solar cell module serves as a heat transferring part that has a higher heat resistance than the outer periphery (12).

### BACKGROUND OF THE INVENTION

1. Field of the Invention

The present invention relates to a terminal box for use with solar cell module.

2. Description of the Related Art

A solar panel constituting a solar power system comprises a plurality of solar cell modules which has respective electrodes connected in series or parallel to each other via a terminal box.

For example, the terminal box includes a shallow box-shaped case made of a synthetic resin, a plurality of terminal boards laid on the bottom in the case and electrically connected to the solar cell modules, and bypass diodes (rectifying devices) for reverse load, which bridge respective corresponding pairs of terminal boards. Each diode includes a body which serves as a heat-generating portion and is supported by a metallic radiator plate. The terminal boards have respective one ends to which leads of the electrode are soldered to be connected through an opening formed in the case. The terminal boards have the other ends onto which terminals of cables drawn out of the case are crimped respectively. The case has an underside bonded to a mounting surface of each solar cell module. Accordingly, upon heat generation of the diode bodies, heat is adapted to be caused to escape from radiator plates through the bottom to the solar cell module side.

Japanese Patent No. 3498945 is an example of the state-of-the-art described above.

When the temperatures of the diode bodies rise during operation of the diodes, the temperature of the bottom of the case is sometimes subjected to plastic deformation over a heat resistance limit of the case. Then, the underside of the case is rendered non-flat such that an air space is interposed between the underside of the case and the mounting surface of the solar cell module under the condition where the solar cell modules are mounted, whereupon there is a possibility that the heat transfer performance of the solar cell module may be reduced.

The present invention was made in view of the foregoing circumstances and an object thereof is to provide a terminal box for use with a solar cell module having a beneficial effect on the heat transfer performance.

### SUMMARY OF THE INVENTION

The present invention is a terminal box for use with a solar cell module, which is mounted on a solar cell module, the terminal box comprising a plurality of terminal boards; a case accommodating the terminal boards and having an outer periphery surrounding the terminal boards; bypass rectifying devices for reverse load, connected to corresponding pairs of the terminal boards; radiator plates on which rectifying device bodies serving as heat generating portions of the rectifying devices are supported, the radiator plates being configured integrally with or independent of the respective terminal boards; and heat transfer portion disposed between the radiator plates and the solar cell module and having a higher heat resistance than the outer periphery.

Since the heat transfer portion has a higher heat resistance than the outer periphery of the case, the heat transfer portion is prevented from plastic deformation due to heat of the rectifying device bodies. Accordingly, intervention of an air space can be avoided between the solar cell module and the heat transfer portion, whereupon the heat transfer performance to the solar cell module can be improved.

The terminal box for use with the solar cell module may be configured as follows:

The case has a bottom which is located inward of the outer periphery and supports the terminal boards, and the bottom may constitute the heat transfer portion. According to this, since the case can be mounted to the solar cell module with the terminal boards being placed on the bottom, the terminal box is advantageous in the mountability.

The bottom is slidingly attached along an inner edge of the outer periphery. According to this, the bottom of the case can easily be attached to the outer periphery.

The terminal boards are fixed to the bottom and at least one of the terminal boards is provided with an open locking hole. The outer periphery is provided with a deflectable locking piece. When the bottom is normally attached to the outer periphery, the locking piece is elastically fitted in the locking hole, whereby the terminal boards and the bottom are held on the outer periphery. According to this, the bottom is fixed via the terminal boards to the outer periphery, whereupon the shape of the bottom is simplified.

When the bottom has normally been attached to the outer periphery, a window opening is opened between the bottom and the outer periphery, and leads corresponding to groups of solar cells of the solar cell modules are drawn through the window opening into the case. This eliminates provision of a window opening specific to the bottom, whereupon the shape of the bottom is simplified.

The bottom and the terminal boards are integrated by insert molding. According to this, the terminal boards are reliably prevented from separation from the bottom.

The heat transfer portion is retained in an externally non-exposed state when mounted to the solar cell module. According to this, for example, the heat transfer portion can be configured by a material with a low weatherproof, whereupon a range of options in the selection of the material for the heat transfer portion is widened.

The heat transfer portion is disposed at least between the rectifying device bodies and the solar cell module. This results in efficient transfer of heat generated by the rectifying device bodies to the heat transfer portion, realizing a further better heat-transfer property.

The outer periphery comprises one or more of PPO (polyphenylene oxide) and PPE (polyphenylene ether), and the heat transfer portion comprises one or more of PPS (polyphenylene sulfide), PET (polyethylene terephthalate) and PBT (polybutylene terephthalate). According to this, the outer periphery is configured by a material having beneficial effects on weatherproof and hydrolysis resistance, while the bottom is configured by a material having beneficial effects on heatproof and heat transfer.

The radiator plates are formed integrally with the terminal boards respectively and the terminal boards include a terminal on which no rectifying device body is supported, said terminal having a smallest surface area. Since each terminal on which the rectifying device body is supported has a larger surface area, the radiation performance of each terminal board can be improved within a limited space in the case.

According to the invention, the terminal box for use with solar cell module having an improved heat transfer performance can be provided.

### BRIEF DESCRIPTION OF THE DRAWINGS

FIG. 1 is a plan view of a terminal box for use with a solar cell module, according to a first embodiment of the present invention;

FIG. 2 is a sectional view taken along line A-A in FIG. 1;

FIG. 3 is a sectional view taken along line B-B in FIG. 1;

FIG. 4 is a sectional view taken along line C-C in FIG. 1;

FIG. 5 is a plan view of a unit in which the terminal boards and the bottom are integrated with each other;

FIG. 6 is a sectional view taken along line D-D in FIG. 5;

FIG. 7 is a bottom view of the unit in which the terminal boards and the bottom are integrated with each other;

FIG. 8 is a plan view of the outer periphery;

FIG. 9 is a side view of a slide support;

FIG. 10 is a bottom view of the case;

FIG. 11 is a plan view of the terminal box for use with the solar cell module according to a second embodiment, showing the bottom on which the terminal boards are mounted; and

FIG. 12 is a plan view of the bottom.

### DETAILED DESCRIPTION OF THE PREFERRED EMBODIMENTS

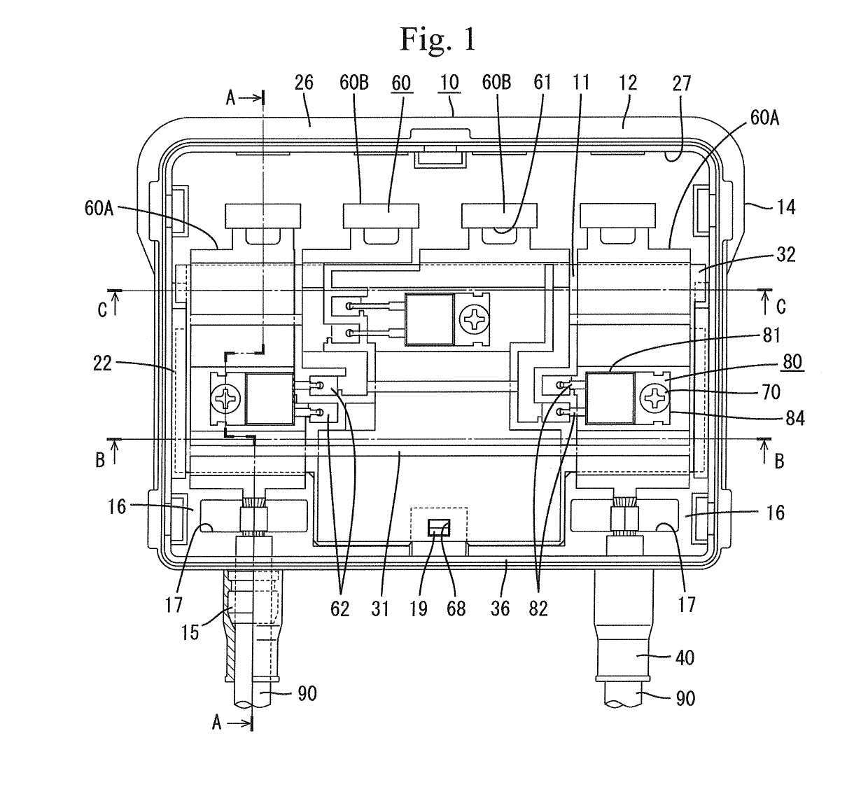

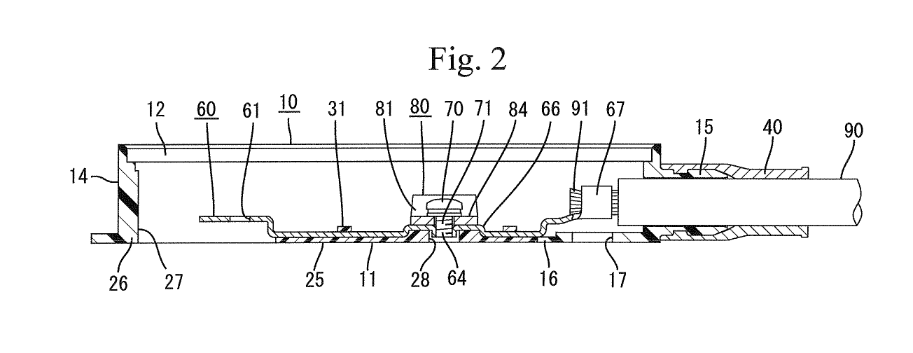

A first embodiment of the present invention will be described with reference to FIGS. 1 to 10. A terminal box for use with a solar cell module (hereinafter, “terminal box”) according to the first embodiment includes a case 10, terminal boards 60 and bypass diodes 80.

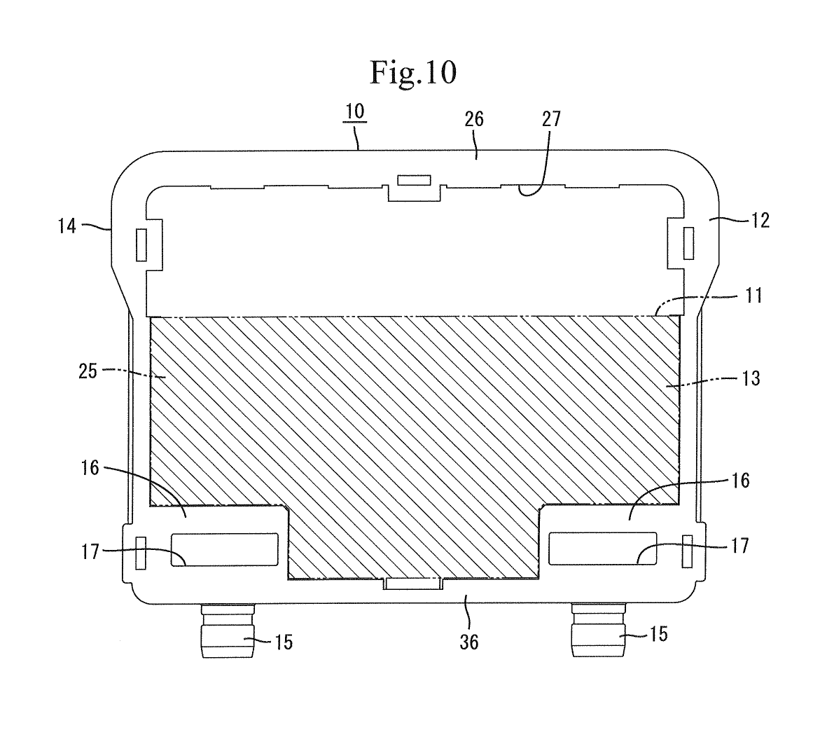

The case 10 is made of a synthetic resin and generally formed into a plate shape and comprises a bottom 11 and an outer periphery 12 surrounding the bottom 11, as shown in FIGS. 1 and 10. The bottom 11 has a bottom surface formed into a flat surface 13 and mounted to the mounting surface of the solar cell module (an underside in use) in a closely adhered state. When the case 10 has been mounted to the solar cell module, the bottom 11 is hidden so as to be in an externally non-exposed state while the outer periphery 12 is exposed to the outside.

The bottom 11 and the outer periphery 12 are independent of each other and are detachably attachable to each other. Furthermore, the bottom 11 and the outer periphery 12 are made of respective materials different from each other. More specifically, the outer periphery 12 is made of any one of materials of PPO (polyphenylene oxide), PPE (polyphenylene ether) and PVC (polyvinyl chloride), whereas the bottom 11 is made of any one of materials of PPS (polyphenylene sulfide), PET (polyethylene terephthalate) and PBT (polybutylene terephthalate). More specifically, the outer periphery 12 is made of a material having a superior weatherproof and hydrolysis resistance, whereas the bottom 11 is made of a material having a higher heat resistance and heat transfer property. Furthermore, the outer periphery 12 is less expensive than the bottom 11.

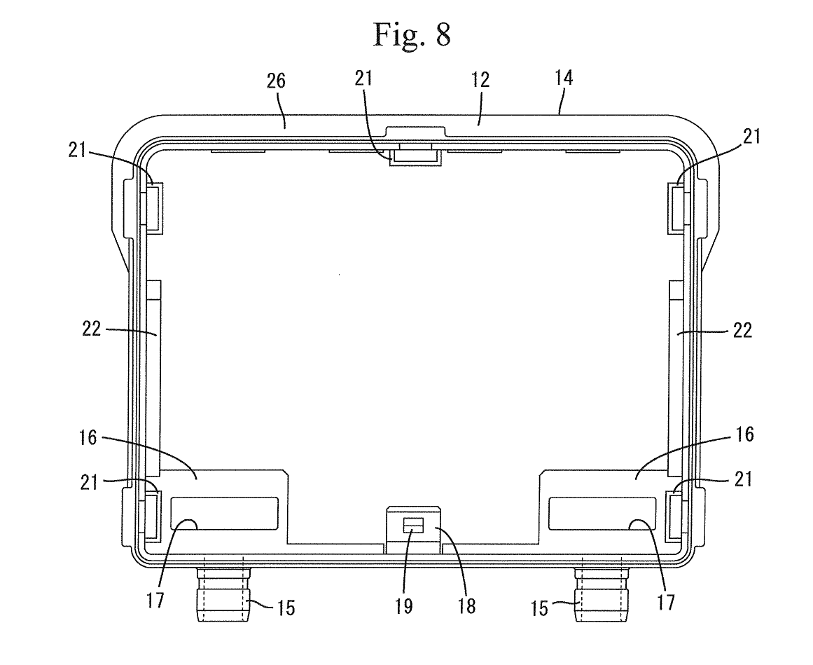

The outer periphery 12 has a rectangular frame-shaped peripheral wall 14 which divides a periphery of the case 10 as shown in FIG. 8. The peripheral wall 14 has a rear end 36 further having right and left sides formed with paired cylindrical portions 15 protruding rearward. Cables 90 which are connected to terminal boards 60 are inserted through the cylindrical portions 15 respectively. Furthermore, the rear end 36 of the peripheral wall 14 has both widthwise ends formed with paired right and left stages 16 located in front of the cylindrical portions 15, respectively. The stages 16 are connected to both end corners of the peripheral wall 14. The stages 16 have centrally located through holes 17 respectively.

A substantially rectangular locking pieces 18 capable of locking the terminal boards 60 is formed on the widthwise central portion of the rear end 36 of the peripheral wall 14 so as to protrude frontward (inward of the peripheral wall 14). The locking piece 18 is elastically deformable in a vertical direction with a point on the inner surface of the peripheral wall 14 serving as a fulcrum point and has a centrally located locking protrusion 19.

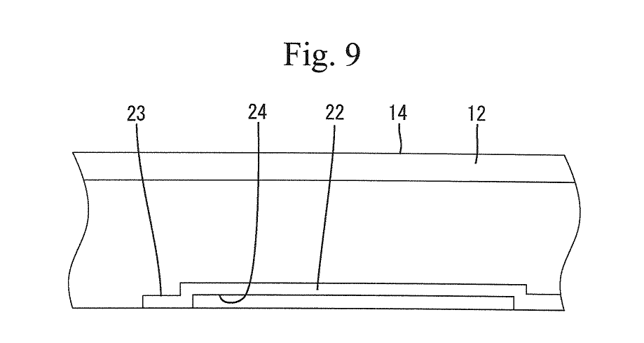

The peripheral wall 14 has an inner peripheral surface on which a plurality of cover lock supports 21 is formed at peripheral intervals. A cover (not shown) has a cover lock which is locked by the cover lock supports 21, whereby the cover is fixed to the upper end of the peripheral wall 14 and held in the fixed state. Furthermore, paired slide supports 22 are formed on the inner peripheral surface of right and left sides of the peripheral wall 14 respectively. Each slide support 22 is formed into an elongate plate shape and extends in the front-back direction along the inner peripheral surface of the peripheral wall 14 as shown in FIG. 9. Each slide support 22 has a front end which is located lower than a rear portion such that each slide support 22 is stepped. The front end of each slide support 22 has an upper surface serving as a first engagement support surface 23 which engages a slide 32 (as will be described later) of the bottom 11 from below. Each slide support 22 includes a part located in the rear of the front end and has an underside serving as a second engagement support surface 24 which engages the slide 32 from above. The first and second engagement support surfaces 23 and 24 serve as horizontal surfaces that occupy substantially the same heightwise positions as each other.

The bottom 11 is formed integrally with the terminal boards 60 by insert molding and has a flat plate-shaped bottom wall 25 supporting the terminal boards 60. The terminal boards 60 are arranged on the upper surface of the bottom wall 25 widthwise in parallel to each other. When the bottom 11 and the outer periphery 12 are connected to each other, a widthwise long window opening 27 is open between a front end of the bottom wall 25 and a rear end of a front end 26 of the peripheral wall 14. Leads (not shown) corresponding to solar cell groups of the solar cell module are adapted to be drawn through the window opening 27 into the case 10.

Each terminal board 60 is made of an electrically conductive metal and formed into the shape of a flat plate. The terminal boards 60 are constituted by paired right and left cable connecting terminals 60A which are located at both widthwise ends thereof and connected to positive and negative cables 90, respectively and right and left relay connecting terminals 60B located between the cable connecting terminals 60A. The outer periphery 12 is disposed around the terminal boards 60. Each terminal board 60 has a front end formed with an insertion hole 61. A terminal of the lead is inserted into the insertion hole 61 to be connected by soldering or the like. Each bypass diode 80 includes a rectifying device body 81 (as will be described later) placed on the upper surface of each terminal board 60 in the middle thereof in the front-back direction, except for the relay connecting terminal 60B located in the left side as viewed in the drawing.

Each bypass diode 80 includes the rectifying device body 81 of the type that a chip thereof is covered with resin into the shape of a square block and anode side and cathode side connecting legs 82 both connected to the chip and widthwise extending from one side of the rectifying device body 81. In this case, the rectifying device body 81 is a heat generating portion whose temperature rises near 200° C. by rectification of the chip. Each terminal board 60 has a function as a radiator plate radiating heat generated by the rectifying device body 81. More specifically, each terminal board 60 is configured to be integral with the radiator plate.

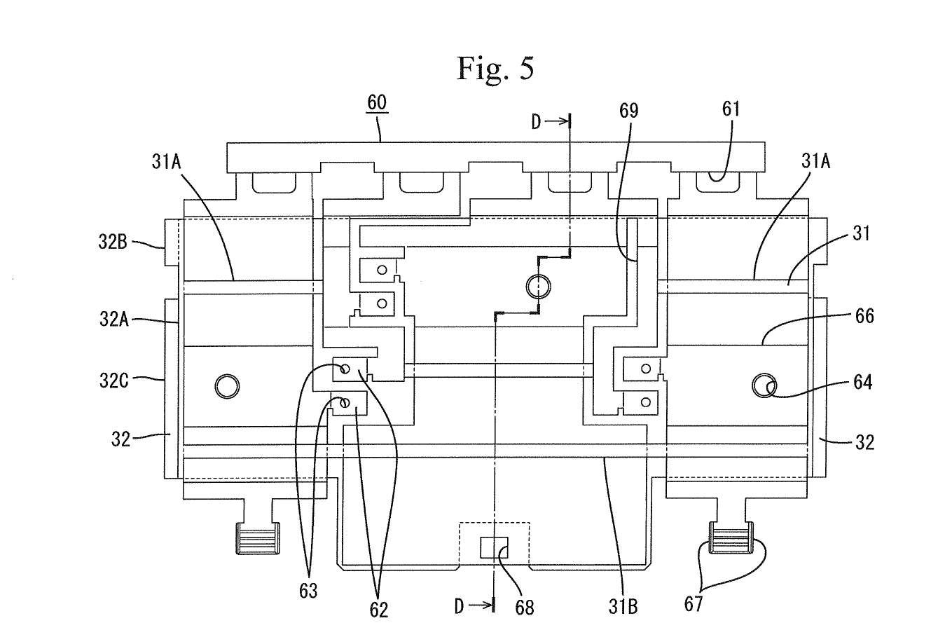

Both connecting legs 82 are disposed so as to be substantially in parallel to each other. One of the connecting legs 82 has a distal end which is soldered thereby to be connected to the terminal board 60 supporting the rectifying device body 81, and the other connecting leg 82 has a distal end which is soldered thereby to be connected to the adjacent terminal board 60. Each terminal board 60 has a side edge on which generally rectangular connection pieces 62 are formed so as to extend widthwise as shown in FIG. 5. Each connection piece 62 has a connecting hole 63 through which the distal end of the connecting leg 82 is inserted to be connected thereto by solder.

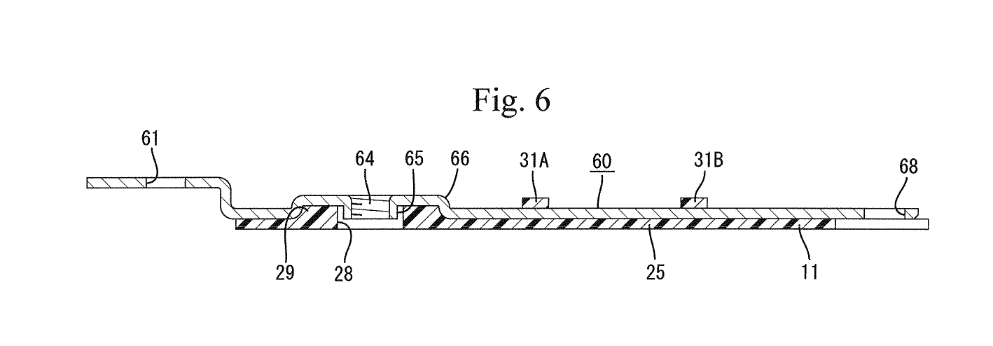

Furthermore, a fixing piece 84 is formed on the other side of the rectifying device body 81 so as to protrude widthwise. A screw member 70 is screwed through the fixing piece 84 such that a threaded portion 71 thereof is threadingly engaged with a screw hole 64 formed in each terminal board 60, whereby the bypass diode 80 is fixed via the screw member 70 to the terminal board 60. A burring portion 65 having the screw hole 64 is formed on the terminal board 60 so as to protrude downward, as shown in FIG. 6. The bottom wall 25 is formed with an escape hole 28 into which the burring portion 65 and the distal end of threaded portion 71 are inserted. The bottom wall 25 is further formed with a stepped thicker wall part 29 having an escape hole 28, and the terminal board 60 is formed with a stepped portion 66 which is bent along an outer surface of the thicker wall part 29 into the shape of a mounting.

Paired right and left barrels 67 are formed on the rear ends of the both cable connecting terminals 60A so as to protrude, respectively. The barrels 67 are crimped onto core wires 91 exposed at terminals of the cables 90 thereby to be connected to the core wires 91, respectively. When the cable connecting terminals 60A are connected to the respective cables 90, the terminals of the cables 90 are adapted to be placed on the stages 16 and anvils (not shown) are inserted into the through holes 17 of the stages 16 from below, and furthermore, a crimper (not shown) is lowered from above such that the barrel 67 holds the core wire 91 between the crimper and the anvil.

Each cable connecting terminals 60A have substantially the same surface area as each other, and the right relay connecting terminal 60B has the largest surface area of all terminal boards 60 as viewed in the drawings. The left relay connecting terminal 60B has the smallest surface area of all terminal boards 60 in the drawings. Since no rectifying device body 81 of the bypass diode 80 is supported on the left relay connecting terminal 60B as viewed in the drawings, the left relay connecting terminal 60B has the smallest surface area. The surface area of the adjacent right relay connecting terminal 60B is accordingly increased such that radiating performance of the right relay connecting terminal 60B is improved and a space efficiency is improved. A generally rectangular locking hole 68 is formed in the widthwise middle of the rear end of the right relay connecting terminal 60B so as to be open as viewed in the drawings. The lock protrusion 19 of the locking piece 18 is elastically fitted in the locking hole 68.

A plurality of slits 69 is formed in the relay connecting terminal 60B. The slits 69 are bent from the root of the connecting piece 62 into a crank shape. The provision of the slits 69 prevents thermal interference between the bypass diodes supported on the respective terminal boards 60. Furthermore, the bypass diodes 80 are disposed in a zigzag arrangement in the widthwise direction in order to avoid thermal interference thereamong. More specifically, the bypass diode 80 supported on the relay connecting terminal 60B is disposed frontward relative to the bypass diodes 80 supported on the respective cable connecting terminals 60A.

A plurality of bridges 31 is formed so as to widthwise extend across the upper surfaces of the terminal boards 60. The bridges 31 are formed into the shape of a narrow band and extend together from the upper surface of the bottom wall 25, holding the terminal boards 60 between the bottom wall 25 and themselves. The bridges 31 include independent board coverage bridges 31A each bridging the respective terminal boards 60 and full-coverage bridges 31B each bridging all the terminal boards 60 together. The full-coverage bridges 31B are located in the rear of the independent board coverage bridges 31A and extend substantially entire width of the bottom wall 25.

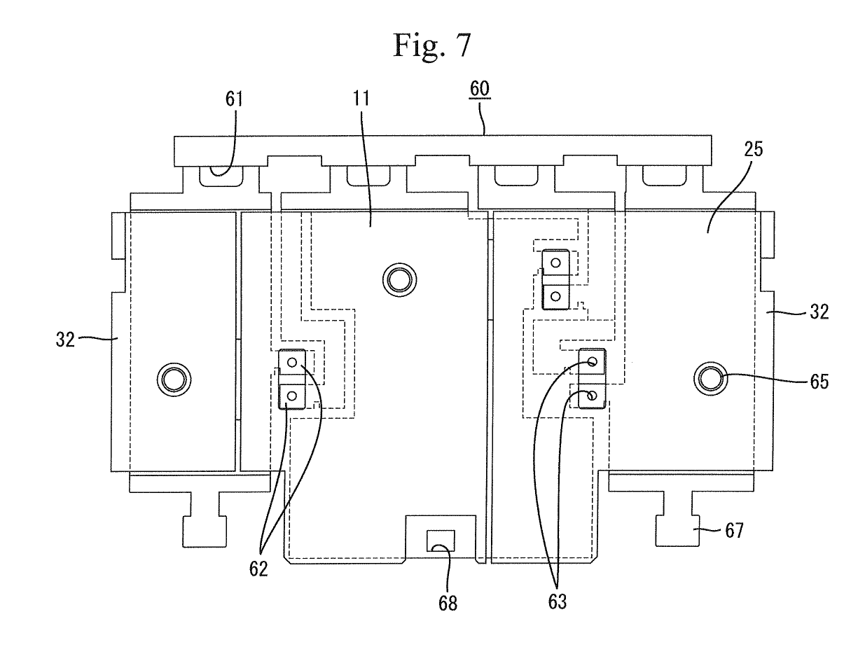

Furthermore, the bottom wall 25 is disposed between the rectifying device body 81 and the solar cell module and is closely adhered to the underside of the terminal boards 60 without covering the barrels 67 of the cable connecting terminals 60A, the burring portion 65, the peripheries of the insertion holes 61, the periphery of the locking hole 68 and the peripheries of the connecting holes 63, as shown in FIG. 7. The bottom wall 25 is divided into three parts for every bypass diode 80. The part of the bottom wall 25 supporting the central bypass diode 80 has the largest surface area. The bottom wall 25 is located between the terminal boards 60 and the solar cell module, whereby the bottom wall 25 has a function of a heat transfer portion which transfers heat generated by the rectifying device bodies 81 to the solar cell module side.

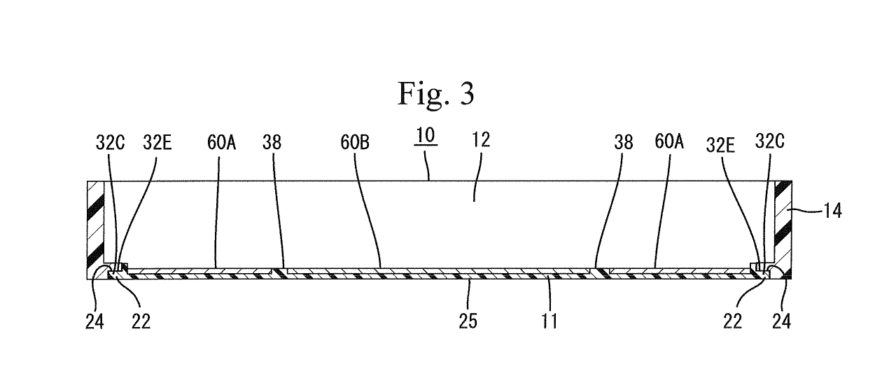

Paired right and left slides 32 are formed on the widthwise ends of the bottom wall 25 respectively. As shown in FIG. 5, each slide 32 has a rib-like slide body 32A extending in the front-back direction, a first slide 32B protruding sideways from a front end of the slide body 32A and a second slide 32C located in the rear of the first slide 32B and protruding sideways from the slide body 32A. The first slide 32B is located higher than the second slide 32C and has an underside having a first engagement surface 32D which is capable of face-to-face contact with the first engagement support surface 23 of the slide support 22. The second slide 32C extends into a slenderer shape than the first slide 32B and has an upper surface having a second engagement surface 32E which is capable of face-to-face contact with the second engagement support surface 24 of the slide support 22 as shown in FIG. 3. The first and second engagement surfaces 32D and 32E are disposed at substantially the same heightwise position. Furthermore, on the upper surface of the bottom wall 25 are formed partition walls 38 separating the terminal boards 60 adjacent to each other.

A manner of assembling the terminal box and advantageous effects thereof will now be described. Firstly, the terminal boards 60 and the bottom 11 are formed by insert molding with the front ends of the terminal boards 60 being connected to each other, whereupon the unit as shown in FIGS. 5 to 7 is constructed. Subsequently, the rectifying device bodies 81 of the bypass diodes 80 are placed on the respective terminal boards 60, and the screw members 70 are threadingly engaged with the screw holes 64 so that the bypass diodes 80 are fixed to the terminal boards 60 respectively. The terminal boards 60 are separated from each other at the front ends on a suitable occasion after the insert molding. Furthermore, soldering is applied to the connecting legs 82 of the bypass diodes 80 inserted into the connecting holes 63 of the terminal boards 60, thereby connecting the bypass diodes 80 to the terminal boards 60, respectively. The work for mounting the bypass diodes 80 may be carried out after attachment of the bottom 11 to the outer periphery 12, which attachment will be described later.

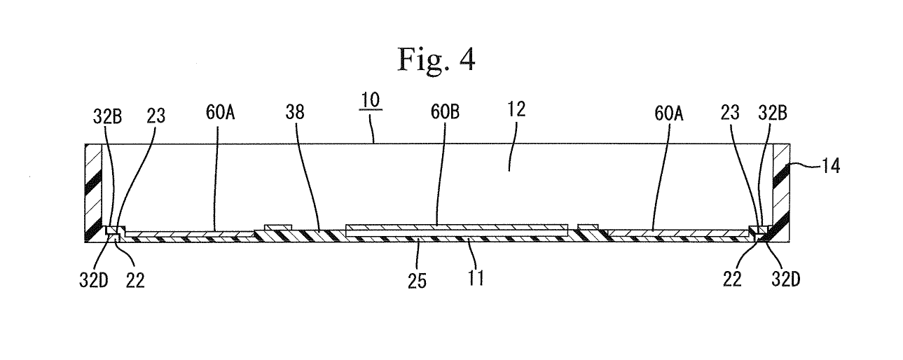

Subsequently, the bottom 11 (the above-described unit) is inserted into the peripheral wall 14 of the outer periphery 12 from below. In this case, the bottom 11 is located slightly forward relative to a normal position thereof. The bottom 11 is moved rearward in this state so that the first engagement support surfaces 23 of the slide supports 22 are slid on the first engagement surfaces 32D of the first slides 32B and so that the second engagement support surfaces 24 of the slide supports 22 are slid on the second engagement surface 32E of the second slides 32C, respectively. When the bottom 11 thus reaches the normal attachment position, the rear end of the bottom wall 25 abut against the front end of the rear end 36 of the outer periphery 12 thereby to be stopped, and the locking protrusion 19 is elastically fitted in the locking hole 68 of the relay connecting terminal 60B with deflection of the locking piece 18. This limits the movement of the bottom 11 in the front-back direction relative to the outer periphery 12. Furthermore, when the bottom 11 reaches the normal attachment position, the first engagement surfaces 32D of the first slides 32B abut against the first engagement support surfaces 23 of the slide supports 22 respectively, whereby the downward displacement of the bottom 11 relative to the outer periphery is limited (see FIG. 4), and furthermore, the second engagement surfaces 32E of the second slides 32C abut against the second engagement support surfaces 24 of the slide supports 22 respectively, whereby the upward movement of the bottom 11 relative to the outer periphery 12 is limited (see FIG. 3). Accordingly, the bottom 11 can be fixed to the outer periphery 12 by a simple operation of sliding the bottom 11 in the peripheral wall 14 of the outer periphery 12.

Subsequently, the cables 90 are inserted into the cylindrical portions 15 of the case 10 from the rear respectively, and the barrel portions 67 of the cable connecting terminals 60A are crimped against the core wires 91 placed on the stages 16 thereby to be connected to the core wires 91, respectively. Furthermore, water-proof caps 40 each made of a resin are attached so as to stride the cylindrical portions 15 and the cable 90 respectively, thereby sealing the cylindrical portions 15 in a water-tight manner.

Subsequently, the underside (the flat surface 13) of the bottom 11 is closely adhered to the mounting surface of the solar cell module, and the case 10 is fixed to the solar cell module by an adhesive agent, double-sided tape, bolt or the like with the bottom 11 being closely adhered to the solar cell module. In the course of the mounting to the solar cell module, leads connected to electrodes of the solar cell module are drawn through the window opening 27 into the case 10 to be solder-joined to the front ends of the terminal boards 60. An insulating resin such as silicon resin is poured into the case 10, and a cover is attached to the case 10 after solidification of the insulating resin.

Meanwhile, when one or more of the rectifying device bodies 81 of the bypass diodes 80 heat up during service, heat is dissipated from the terminal boards 60 through the bottom 11 to the solar cell module side. In this case, since the bottom 11 is made of PPS (polyphenylene sulfide) that has heat resistance and heat transfer property both superior to the outer periphery 12, the terminal box can be structured so as to be hard to be subjected to damage due to heat. Accordingly, the bottom 11 can be prevented from plastic deformation due to heat generation of the rectifying device bodies 81, whereupon the flatness of the underside of the bottom 11 can be retained. Consequently, interposition of air space can be avoided between the underside of the bottom 11 and the mounting surfaces of the bypass diodes 80, whereupon the performance of heat transfer to the solar cell module side can be improved.

According to the foregoing embodiment, furthermore, since the bottom 11 of the case 10 composes the heat transfer portion, the case 10 can be mounted to the solar cell module with the terminal boards 60 being placed on the bottom 11, whereupon the terminal box excels in the mountability. Furthermore, since the slides 32 are slid along the slide supports 22 respectively so that the bottom 11 is slidingly attached along the inner edge of the outer periphery 12, the bottom 11 and the outer periphery 12 can easily be integrated together. Still furthermore, since the bottom 11 and the terminal boards 60 are integrated together by the insert molding, the terminal boards 60 can reliably be prevented from separation from the bottom 11.

Moreover, since the bottom 11 is retained so as not to be externally exposed, the bottom 11 may be made of a material with a low weatherproof performance. This can broaden the range of material selection of the bottom 11. Additionally, since the bottom 11 is necessarily located at positions opposed to the portions supporting the respective rectifying device bodies 81, heat generated at the rectifying device bodies 81 is efficiently transferred to the bottom 11, whereupon more desirable heat transfer property can be realized.

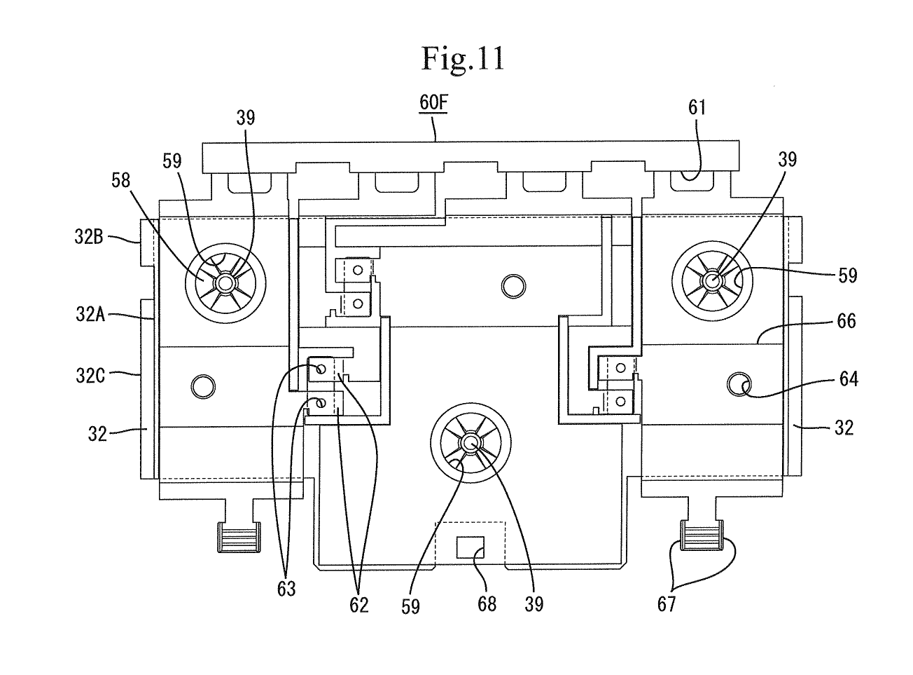

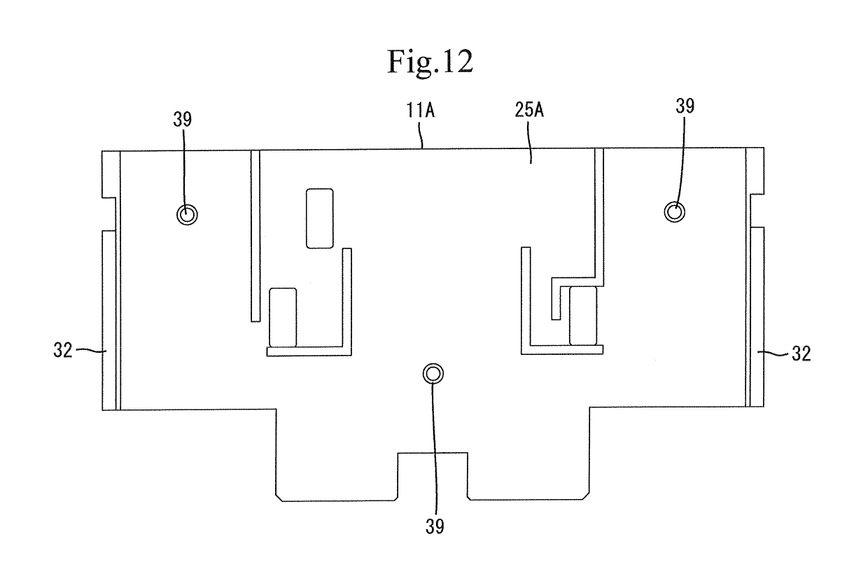

FIGS. 11 and 12 illustrate a second embodiment of the present invention. The second embodiment differs from the first embodiment in that the terminal boards 60F and the bottom 11A are not insert-molded. The second embodiment is the same as the first embodiment in the other respects, and identical or similar parts in the second embodiment are labeled by the same reference symbols as those in the first embodiment.

Circular mounting holes 59 are formed through the terminal boards 60F except for the left relay connecting terminal 60B as viewed in the drawing. A plurality of locking pieces 58 is formed on an opening edge of each mounting hole 59 so as to be circumferentially arranged. Each locking piece 58 is formed into a generally radial shape and is elastically deformable in the vertical direction.

The bottom wall 25A of the bottom 11A has columnar protrusions 39 which are located so as to correspond to the mounting holes 59 respectively. When the terminal boards 60F are placed on the upper surface of the bottom wall 25A with the front ends thereof being connected to one another, the protrusions 39 are inserted into the mounting holes 59 from below such that distal ends of the locking pieces 58 bite into outer circumferential surfaces of the protrusions 39 respectively, whereby the terminal boards 60F can be prevented from separation from the bottom 11A. Subsequently, the front ends of the terminal boards 60F are cut off from one another. The second embodiment is the same as the first embodiment in a manner of mounting the bypass diodes 80 to respective terminal boards 60F, a manner of mounting the bottom 11A to the outer periphery 12, a manner of installing the case 10 into the solar cell module, and the like, and accordingly, overlapping description will be eliminated.

The invention should not be limited by the embodiments described above with reference to the drawings, and the following embodiments encompass the technical scope of the invention:

The heat transfer portion made of a metal may be interposed between the terminal boards and the solar cell module, instead of the bottom. In this case, it is better that the metal heat transfer portion is provided for every terminal board. This can prevent a short circuit between the terminal boards.

The heat transfer portion having higher heat resistance than the outer periphery is interposed between the terminal boards and the solar cell module in the foregoing embodiments. However, the heat transfer portion may be configured not to be integrated with the outer periphery.

The plate members supporting the respective diodes may be configured to be independent of the terminal boards and may be mere heat radiating plates each having no function of the terminal (a connecting portion of an electric circuit).

Each terminal board may be constituted only by a pair of cable connecting terminals and one bypass diode may be configured to extend between both cable connecting terminals.

1. A terminal box for use with a solar cell module, which is mounted on a solar cell module, the terminal box comprising:
a plurality of terminal boards;
a case accommodating the terminal boards and having an outer periphery surrounding the terminal boards;
bypass rectifying devices for reverse load, connected to corresponding pairs of the terminal boards;
radiator plates on which rectifying device bodies serving as heat generating portions of the rectifying devices are supported, the radiator plates being configured integrally with or independent of the respective terminal boards; and
heat transfer portion disposed between the radiator plates and the solar cell module and having a higher heat resistance than the outer periphery.

2. The terminal box according to claim 1, wherein the case has a bottom which is located inward of the outer periphery and supports the terminal boards, and the bottom constitutes the heat transfer portion.

3. The terminal box according to claim 2, wherein the bottom is slidingly attached along an inner edge of the outer periphery.

4. The terminal box according to claim 3, wherein:
the terminal boards are fixed to the bottom and at least one of the terminal boards is provided with an open locking hole;
the outer periphery is provided with a deflectable locking piece; and
when the bottom is normally attached to the outer periphery, the locking piece is elastically fitted in the locking hole, whereby the terminal boards and the bottom are held on the outer periphery.

5. The terminal box according to claim 4, wherein when the bottom is normally attached to the outer periphery, a window opening is opened between the bottom and the outer periphery, and leads corresponding to groups of solar cells of the solar cell module are drawn through the window opening into the case.

6. The terminal box according to claim 2, wherein the bottom and the terminal boards are integrated together by insert molding.

7. The terminal box according to claim 1, wherein the heat transfer portion is retained in an externally non-exposed state when mounted to the solar cell module.

8. The terminal box according to claim 1, wherein the heat transfer portion is disposed between the rectifying device bodies and the solar cell module.

9. The terminal box according to claim 1, wherein the outer periphery comprises one or more of PPO (polyphenylene oxide) and PPE (polyphenylene ether), and the heat transfer portion comprises one or more of PPS (polyphenylene sulfide), PET (polyethylene terephthalate) and PBT (polybutylene terephthalate).

10. The terminal box according to claim 1, wherein:
the radiator plates are formed integrally with the terminal boards respectively; and
the terminal boards include a terminal on which no rectifying device body is supported, said terminal having a smallest surface area.
